(19) United States
(12) Patent Application Publication
(10) Pub. No.: US 2026/0165018 A1
(43) Pub. Date: Jun. 11, 2026

(54) DISPLAY PANEL, ELECTRONIC APPARATUS INCLUDING THE SAME, AND METHOD OF MANUFACTURING ELECTRONIC APPARATUS

(71) Applicant: Samsung Display Co., LTD., Yongin-si (KR)

(72) Inventors: Jinhyoung Kim, Yongin-si (KR); Yongkwon Soh, Yongin-si (KR); Yeonwoo Kim, Yongin-si (KR)

(21) Appl. No.: 19/180,942

(22) Filed: Apr. 16, 2025

(30) Foreign Application Priority Data
Oct. 25, 2024 (KR) 10-2024-0147865

(51) Int. Cl. H10K 77/10; H10K 59/12; H10K 59/131; H10K 102/00

(52) U.S. Cl. CPC H10K 77/111; H10K 59/1201; H10K 59/131; H10K 2102/311

(57) ABSTRACT

A display panel includes a substrate comprising a first area, a second area, and a bending area between the first area and the second area, a driving circuit chip disposed in the second area of the substrate, and a cover film disposed in the second area of the substrate to cover the driving circuit chip and including at least one groove. The at least one groove of the cover film is defined in the second area and is defined over a portion of the cover film in a thickness direction of the cover film.

This application claims priority to Korean Patent Application No. 10-2024-0147865, filed on Oct. 25, 2024, and all the benefits accruing therefrom under 35 U.S.C. § 119, the content of which in its entirety is herein incorporated by reference.

### BACKGROUND

### 1. Field

Embodiments relate to a display panel, an electronic apparatus including the display panel, and a method of manufacturing an electronic apparatus by the display panel.

### 2. Description of the Related Art

An electronic apparatus may include a display panel as a component for displaying images and/or videos. The electronic apparatus may also include a housing for accommodating the display panel. The display panel may be coupled to the housing by means of an adhesive or the like.

The display panel may include a substrate partitioned into a display area and a peripheral area. A plurality of pixels may be arranged in the display area. The display area may include thin film transistors respectively corresponding to the pixels and light-emitting diodes electrically connected to the thin film transistors. The display panel may display images and/or videos through the light-emitting diodes. The peripheral area may include various lines for transmitting electrical signals to the display area, a driver, a controller, and the like.

### SUMMARY

A display panel may be coupled to a housing by means of an adhesive or the like. For example, the display panel and the housing may be coupled (e.g., adhered) to each other by applying an adhesive to a predetermined area of the display panel and then bringing the display panel into contact with the housing. In the process of applying the adhesive to the display panel, the adhesive may be excessively applied (i.e., overapplied) or applied to a wrong position (i.e., misapplied). When such an adhesive application error occurs, the display panel and the housing may have to be discarded. This may lead to a decrease in production efficiency and an increase in production costs.

Additional features will be set forth in part in the description which follows and, in part, will be apparent from the description, or may be learned by practice of the presented embodiments of the disclosure.

In an embodiment of the disclosure, a display panel includes a substrate including a first area, a second area, and a bending area between the first area and the second area, a driving circuit chip disposed in the second area of the substrate, and a cover film disposed in the second area of the substrate to cover the driving circuit chip and defining at least one groove. The at least one groove of the cover film is defined in the second area and is defined over a portion of the cover film in a thickness direction of the cover film.

In an embodiment, the at least one groove may be provided in a closed-loop shape.

In an embodiment, the closed-loop shape of the at least one groove may define at least one adhesive area.

In an embodiment, the at least one groove may be provided in plural so that a plurality of grooves, each having the closed-loop shape, may be spaced apart from each other.

In an embodiment, a shape of one of the plurality of grooves may be different from a shape of another one of the plurality of grooves.

In an embodiment, the cover film may include a first layer, a second layer, and a third layer, and the at least one groove may pass through the third layer.

In an embodiment, a first portion of the third layer of the cover film may be spaced apart from a second portion of the third layer by the at least one groove.

In an embodiment, the cover film may further include an adhesive layer between the second layer and the third layer, and the at least one groove may pass through the third layer and the adhesive layer.

In an embodiment, the substrate may be bent in the bending area, and the second area of the substrate, the driving circuit chip, and the cover film may be disposed under the first area of the substrate.

In an embodiment of the disclosure, an electronic apparatus includes a housing and a display panel coupled to the housing, the display panel including a substrate including a first area, a second area, and a bending area between the first area and the second area, a driving circuit chip disposed in the second area of the substrate, and a cover film disposed in the second area of the substrate to cover the driving circuit chip and defining at least one groove. The at least one groove of the cover film is disposed in the second area and is defined over a portion of the cover film in a thickness direction of the cover film, and the housing and the display panel are coupled through an adhesive disposed in an adhesive area defined by the at least one groove of the cover film of the display panel.

In an embodiment of the disclosure, a method of manufacturing an electronic apparatus includes coupling a display panel to a housing, the display panel including a substrate including a first area, a second area, and a bending area between the first area and the second area, a driving circuit chip disposed in the second area of the substrate, and a cover film disposed in the second area of the substrate to cover the driving circuit chip and defining at least one groove. The at least one groove of the cover film is defined in the second area and is defined over a portion of the cover film in a thickness direction of the cover film, and the process of coupling the display panel and the housing includes a process of arranging an adhesive on the cover film of the display panel and adhering the display panel and the housing to each other.

In an embodiment, the at least one groove may be provided in a closed-loop shape defining an adhesive area, and at least a portion of the adhesive may be disposed in the adhesive area.

In an embodiment, the cover film may include a first layer, a second layer, and a third layer and the at least one groove may pass through the third layer, and a first portion of the third layer corresponding to the adhesive area may be spaced apart from a second portion of the third layer by the at least one groove.

In an embodiment, a portion of the adhesive may be disposed over the first portion of the third layer, and another portion of the adhesive may be disposed in the at least one groove beyond the first portion of the third layer.

In an embodiment, the method may further include removing the adhesive and the first portion of the third layer together.

In an embodiment, the method may further include arranging a new adhesive in an opening defined by removing the first portion of the third layer.

In an embodiment, the at least one groove defining the adhesive area is provided in plural so that a plurality of grooves having a plurality of closed-loop shapes define a plurality of adhesive areas spaced apart from each other.

In an embodiment, a closed-loop shape of one of the plurality of grooves may be different from a closed-loop shape of another one of the plurality of grooves.

In an embodiment, the method may further include determining whether the adhesive is normally disposed.

In an embodiment, the method may further include bending the substrate in the bending area such that the second area of the substrate, the driving circuit chip, and the cover film are disposed under the first area of the substrate.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of an electronic apparatus;

FIG. 2 is a schematic plan view of an embodiment of a display panel;

FIG. 3 is a circuit diagram schematically illustrating an embodiment of a light-emitting diode included in a pixel of a display panel and a pixel circuit connected thereto;

FIG. 4 is a cross-sectional view illustrating an embodiment of a portion of a display area of a display panel;

FIGS. 5A, 5B, and 5C are bottom views of display panels according to various embodiments;

FIGS. 6A and 6B are cross-sectional views of display panels according to various embodiments;

FIGS. 7A and 7B are cross-sectional views of portions of display panels according to various embodiments;

FIG. 8 is a flowchart illustrating an embodiment of processes of an electronic apparatus manufacturing method;

FIG. 9 is a bottom view schematically illustrating an embodiment of a process of an electronic apparatus manufacturing method;

FIG. 10A is a bottom view schematically illustrating an embodiment of a process of an electronic apparatus manufacturing method;

FIG. 10B is a cross-sectional view of a display panel taken along line X-X′ of FIG. 10A;

FIG. 11A is a bottom view schematically illustrating an embodiment of a process of an electronic apparatus manufacturing method;

FIG. 11B is a cross-sectional view of a display panel taken along line XI-XI′ of FIG. 11A;

FIG. 12A is a bottom view schematically illustrating an embodiment of a process of an electronic apparatus manufacturing method;

FIG. 12B is a cross-sectional view of a display panel taken along line XII-XII′ of FIG. 12A;

FIG. 13A is a bottom view schematically illustrating an embodiment of a process of an electronic apparatus manufacturing method;

FIG. 13B is a cross-sectional view of a display panel taken along line XIII-XIII′ of FIG. 13A;

FIG. 14A is a bottom view schematically illustrating an embodiment of a process of an electronic apparatus manufacturing method; and

FIG. 14B is a cross-sectional view of a display panel taken along line XIV-XIV′ of FIG. 14A.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become apparent with reference to the embodiments described below in detail together with the drawings. However, the disclosure is not limited to the embodiments described below and may be implemented in various forms.

Hereinafter, embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element.

As used herein, the singular forms “a,” “an,” and “the” are intended to include the plural forms as well, unless the context clearly indicates otherwise.

It will be understood that terms such as “comprise,” “include,” and “have” used herein specify the presence of stated features or elements, but do not preclude the presence or addition of one or more other features or elements.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

Sizes of components in the drawings may be exaggerated for convenience of description. In other words, because the sizes and shapes of components in the drawings are arbitrarily illustrated for convenience of description, the disclosure is not limited thereto.

When an illustrative embodiment may be implemented differently, a particular process order may be performed differently from the described order. For example, two consecutively described processes may be performed substantially at the same time or performed in an order opposite to the described order.

It will be understood that when a layer, region, area, component, or element is referred to as being “connected to” another layer, region, area, component, or element, it may be “directly connected to” the other layer, region, area, component, or element or may be “indirectly connected to” the other layer, region, area, component, or element with one or more intervening layers, regions, areas, components, or elements therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components therebetween.

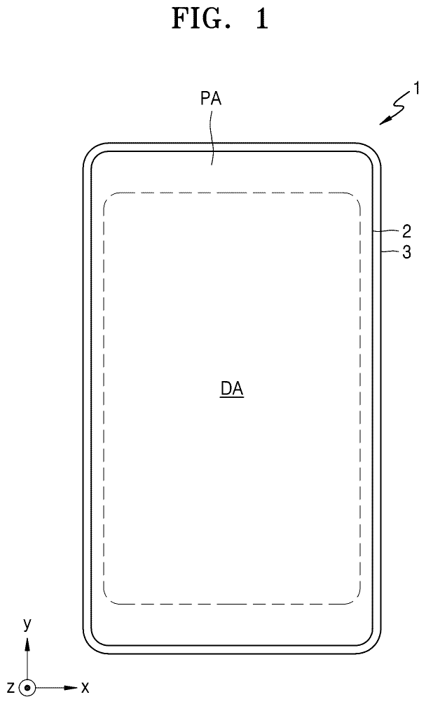

FIG. 1 is a schematic plan view of an embodiment of an electronic apparatus 1.

The electronic apparatus 1 may include a display panel 2 and a housing 3. In an embodiment, the display panel 2 may be accommodated in the housing 3.

In an embodiment, the electronic apparatus 1 may include various products such as televisions, notebook computers, monitors, billboards, and Internet of Things (“IoT”) devices as well as portable electronic devices such as mobile phones, smart phones, tablet personal computers, mobile communication terminals, electronic notebooks, electronic books, portable multimedia players (“PMPs”), navigation, and ultra mobile personal computers (“UMPCs”). In an embodiment, the electronic apparatus 1 may include wearable devices such as smart watches, watch phones, glasses-type displays, and head-mounted displays (“HMDs”). In an embodiment, the electronic apparatus 1 may include a center information display (“CID”) disposed at a vehicle's instrument panel or a vehicle's center fascia or dashboard, a room mirror display replacing a vehicle's side mirror, or a display disposed at a rear side of a vehicle's front seat as an entertainment for a vehicle's rear seat. The display panel 2 may be provided to the electronic apparatus 1 as a component that displays moving images or still images in various embodiments of the electronic apparatus 1 described above.

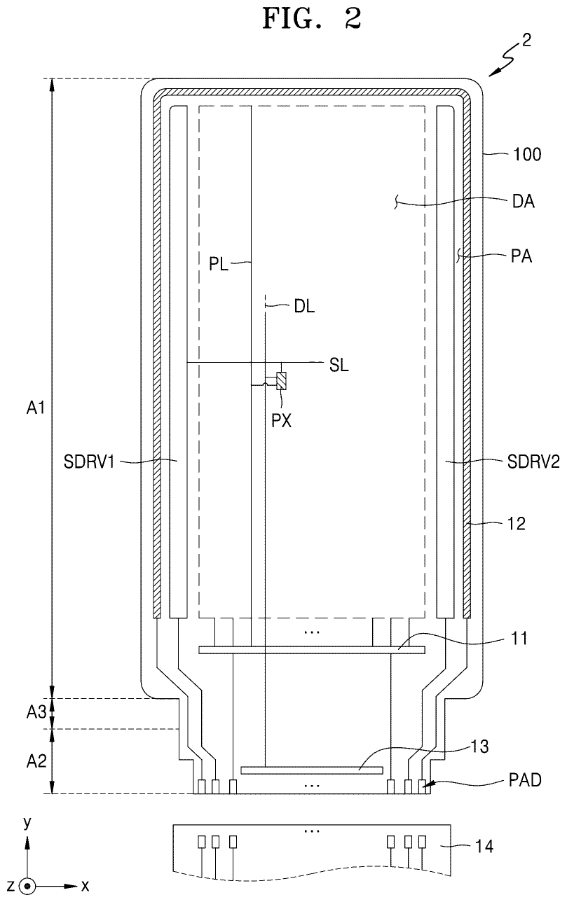

The display panel 2 may include a display area DA and a peripheral area PA outside (or around) the display area DA. Also, because the display panel 2 may include a substrate 100 (refer to FIG. 2), it may be understood that the substrate 100 includes the display area DA and the peripheral area PA. In an alternative embodiment, it may be understood that the display area DA and the peripheral area PA are defined in the substrate 100.

The display area DA may be an area for displaying an image, and a plurality of pixels may be arranged in the display area DA. In an embodiment, the display area DA may have any of various shapes such as a circular shape, an elliptical shape, a polygonal shape, and a particular figure shape, for example. In an alternative embodiment, the display area DA may have an atypical shape. FIG. 1 illustrates an embodiment in which the display area DA has a substantially tetragonal (e.g., rectangular) shape with rounded corners.

The peripheral area PA may be disposed outside the display area DA. The peripheral area PA may surround at least a portion of the display area DA.

Hereinafter, an organic light-emitting display panel will be described in an embodiment of the display panel 2; however, the display panel of the disclosure is not limited thereto. In another embodiment, the display panel 2 of the disclosure may be an inorganic light-emitting display panel (or an inorganic electroluminescence (“EL”) display panel) or may be a display panel such as a quantum dot light-emitting display panel. In an embodiment, an emission layer of a display element (e.g., a light-emitting diode) included in the display panel 2 may include an organic material, may include an inorganic material, may include quantum dots, may include an organic material and quantum dots, or may include an inorganic material and quantum dots, for example.

FIG. 2 is a schematic plan view of a display panel 2.

Referring to FIG. 2, the display panel 2 may include a substrate 100. Various components included in the display panel 2 may be arranged over the substrate 100. The substrate 100 may include a display area DA and a peripheral area PA outside the display area DA. Herein, an expression such as ‘a component being disposed in the display area DA’ may mean that the component is disposed over the substrate 100 in the display area DA or may be disposed overlapping the display area DA of the substrate 100. Similarly, herein, that a component is disposed in the peripheral area PA may mean that the component is disposed over the substrate 100 in the peripheral area PA or may be disposed overlapping the peripheral area PA of the substrate 100.

The display panel 2 may include a first area A1, a second area A2, and a third area A3. The third area A3 may be disposed between the first area A1 and the second area A2. The first area A1 may include the display area DA and a portion of the peripheral area PA. Each of the second area A2 and the third area A3 may include a portion of the peripheral area PA. In an embodiment, the third area A3 may be a bending area. In an embodiment, the display panel 2 may be bent in the third area A3, and the second area A2 and the components of the display panel 2 arranged in the second area A2 may be disposed in the −z direction of the first area A1 and the components of the display panel 2 arranged in the first area A1. For convenience of description, FIG. 2 illustrates a state in which the display panel 2 is unfolded.

A plurality of pixels PX may be arranged in the display area DA. Each of the pixels PX may include a light-emitting diode as a display element. Each of the pixels PX may include a pixel circuit that drives the light-emitting diode. The pixels PX may emit red, green, blue, or white light. Herein, the term “pixel” may also be understood as referring to a plurality of “subpixels” that are grouped into a pixel, for example.

The pixel circuits of the pixels PX may be connected to a signal line and/or a voltage line for controlling the on/off and brightness of the light-emitting diode. In an embodiment, the signal line may include a scan line SL extending in the ±x direction and a data line DL extending in the ±y direction. In an embodiment, the voltage line may include a driving voltage line PL.

The peripheral area PA may be a non-display area that does not display an image. The peripheral area PA may surround an entirety of the display area DA. Peripheral circuits for driving the pixels PX may be arranged in the peripheral area PA. In an embodiment, a first scan driver SDRV1, a second scan driver SDRV2, a driving circuit chip 13, a plurality of terminals PAD, a first voltage supply line 11, and a second voltage supply line 12 may be arranged in the peripheral area PA, for example.

In an embodiment, the first voltage supply line 11 may be a driving voltage supply line. In an embodiment, the second voltage supply line 12 may be a common voltage supply line. In an embodiment, the first scan driver SDRV1, the second scan driver SDRV2, the first voltage supply line 11, and the second voltage supply line 12 may be arranged in the first area A1 and may be connected to lines that are connected to the plurality of terminals PAD by extending through the third area A3 to the second area A2. In an embodiment, the driving circuit chip 13 may be disposed in the second area A2.

The first scan driver SDRV1 may apply a scan signal to each of the pixel circuits of the pixels PX through the scan line SL. The second scan driver SDRV2 may be disposed on the opposite side of the first scan driver SDRV1 with respect to the display area DA and may be substantially parallel to the first scan driver SDRV1. Some of the pixel circuits of the pixels PX arranged in the display area DA may be electrically connected to the first scan driver SDRV1, and some others may be electrically connected to the second scan driver SDRV2.

The driving circuit chip 13 may include an integrated circuit for driving the display panel 2. The integrated circuit may be a data driving integrated circuit for generating a data signal; however, the disclosure is not limited thereto. The driving circuit chip 13 may be electrically connected through terminals (e.g., the plurality of terminals PAD) to a printed circuit board 14 attached to one side of the display panel 2. In another embodiment, the driving circuit chip 13 may be provided over the printed circuit board 14.

The plurality of terminals PAD may be arranged on one side of the substrate 100 (e.g., in the second area A2). The plurality of terminals PAD may be connected to the printed circuit board 14 by being exposed without being covered by an insulating layer.

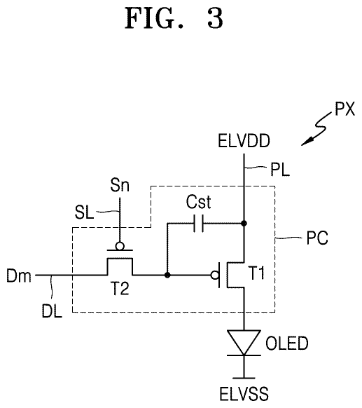

A controller (not illustrated) may be disposed on the printed circuit board 14. The controller may generate a control signal transmitted to the first scan driver SDRV1 and the second scan driver SDRV2. Also, the controller may supply a driving voltage ELVDD (refer to FIG. 3) to the first voltage supply line 11 and may supply a common voltage ELVSS (refer to FIG. 3) to the second voltage supply line 12. The driving voltage ELVDD may be applied to the pixel circuits of the pixels PX through the driving voltage line PL connected to the first voltage supply line 11. The common voltage ELVSS may be applied to an opposite electrode of the light-emitting diode connected to the second voltage supply line 12. The first voltage supply line 11 may be provided extending in the ±x direction on the lower side of the display area DA. The second voltage supply line 12 may have a shape in which one side is open in a loop shape, to partially surround the display area DA. However, the disclosure is not limited to the particular shape of the first voltage supply line 11 and the second voltage supply line 12.

The controller may generate a data signal, and the generated data signal may be transmitted to the data line DL through the driving circuit chip 13. The data signal may be sequentially transmitted to the pixels PX disposed in the same column through the data lines DL extending in the ±y direction.

FIG. 3 is a circuit diagram schematically illustrating an embodiment of a light-emitting diode included in a pixel PX of a display panel and a pixel circuit PC connected thereto.

Referring to FIG. 3, the pixel circuit PC may be connected to a light-emitting diode such as an organic light-emitting diode OLED to implement light emission of pixels PX. The pixel circuit PC may include a first transistor T1, a second transistor T2, and a storage capacitor Cst. In an embodiment, the first transistor T1 may be a driving transistor, and the second transistor T2 may be a switching transistor.

The second transistor T2 may be connected to a scan line SL and a data line DL. The second transistor T2 may transmit a data signal Dm input through the data line DL, to the first transistor T1 according to a scan signal Sn input through the scan line SL.

The storage capacitor Cst may be connected to the second transistor T2 and a driving voltage line PL. The storage capacitor Cst may store a voltage corresponding to the difference between a voltage received from the second transistor T2 and a driving voltage ELVDD supplied to the driving voltage line PL.

The first transistor T1 may be connected to the driving voltage line PL and the storage capacitor Cst. The first transistor T1 may control a driving current flowing from the driving voltage line PL through the organic light-emitting diode OLED, in response to a voltage value stored in the storage capacitor Cst. The organic light-emitting diode OLED may emit light with a predetermined brightness according to the driving current.

The pixel circuit PC is not limited to the number and circuit design of the transistors and storage capacitor described with reference to FIG. 3, and the number and circuit design thereof may be variously modified.

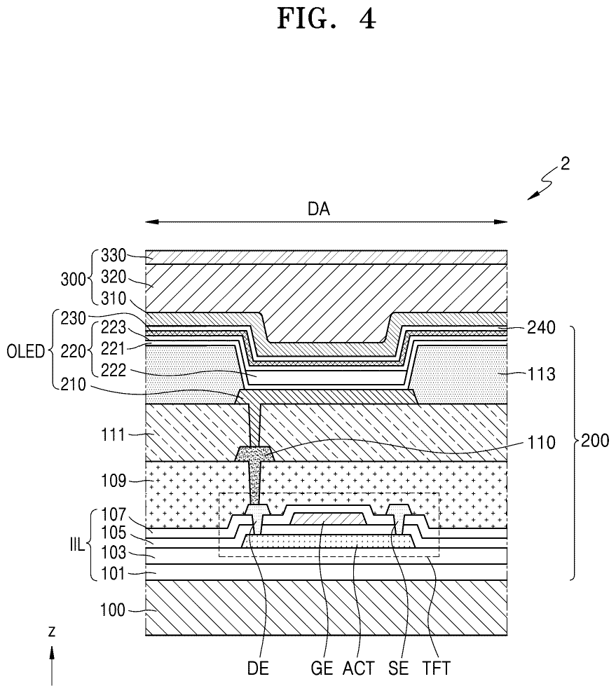

FIG. 4 is a cross-sectional view illustrating an embodiment of a portion of a display area DA of a display panel DP.

Referring to FIG. 4, a display element layer 200 and an encapsulation layer 300 may be arranged over a substrate 100. The display element layer 200 may include an inorganic insulating layer IIL, a thin film transistor TFT, and an organic light-emitting diode OLED. The organic light-emitting diode OLED may be electrically connected to the thin film transistor TFT. The inorganic insulating layer IIL may include a plurality of layers, and components of the thin film transistor TFT may be arranged between the layers of the inorganic insulating layer IIL. In an embodiment, the inorganic insulating layer IIL may include a barrier layer 101, a buffer layer 103, a gate insulating layer 105, and an inter-insulating layer 107.

The barrier layer 101 and the buffer layer 103 may be arranged over the substrate 100. The barrier layer 101 and the buffer layer 103 may planarize and protect the upper surface of the substrate 100. The barrier layer 101 and the buffer layer 103 may include an inorganic insulating material. In an embodiment, each of the barrier layer 101 and the buffer layer 103 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer structure or a multilayer structure, for example.

The thin film transistor TFT may be disposed over the buffer layer 103. The thin film transistor TFT may include an active layer ACT, a gate electrode GE, a source electrode SE, and a drain electrode DE. The thin film transistor TFT may be connected to the organic light-emitting diode OLED to drive the organic light-emitting diode OLED. In an embodiment, the thin film transistor TFT may be the first transistor T1 described above with reference to FIG. 3.

The active layer ACT may be disposed over the buffer layer 103. The active layer ACT may include a drain area overlapping the drain electrode DE, a source area overlapping the source electrode SE, and a channel area disposed between the drain area and the source area. The drain area and the source area may be areas doped with impurities (i.e., dopants).

The gate insulating layer 105 may be disposed over the active layer ACT. The gate insulating layer 105 may include an inorganic insulating material. In an embodiment, the gate insulating layer 105 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer structure or a multilayer structure, for example. In an embodiment, the gate insulating layer 105 may cover an entirety of the active layer ACT as illustrated in FIG. 4. In an embodiment, the gate insulating layer 105 may be patterned to cover only a partial area of the active layer ACT (e.g., an area overlapping the gate electrode GE, that is, a channel area).

The gate electrode GE may be disposed over the gate insulating layer 105. The gate electrode GE may overlap the active layer ACT. In an embodiment, the gate electrode GE may overlap the channel area of the active layer ACT, for example. The gate electrode GE may include at least one of aluminum (Al), platinum (Pt), palladium (Pd), silver (Ag), magnesium (Mg), gold (Au), nickel (Ni), neodymium (Nd), iridium (“IR”), chromium (Cr), calcium (Ca), molybdenum (Mo), titanium (Ti), tungsten (W), and copper (Cu) and may have a single-layer structure or a multilayer structure.

The inter-insulating layer 107 may be disposed to cover the gate electrode GE. The inter-insulating layer 107 may include an inorganic insulating material. In an embodiment, the inter-insulating layer 107 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂) and may have a single-layer structure or a multilayer structure, for example.

The gate insulating layer 105 and the inter-insulating layer 107 may include a contact hole overlapping the source area of the active layer ACT and a contact hole overlapping the drain area. The source electrode SE and the drain electrode DE may be arranged over the inter-insulating layer 107. The source electrode SE may overlap the source area of the active layer ACT, and the drain electrode DE may overlap the drain area of the active layer ACT. Each of the source electrode SE and the drain electrode DE may be connected to the active layer ACT through a contact hole defined in the gate insulating layer 105 and the inter-insulating layer 107.

A first organic insulating layer 109 and a second organic insulating layer 111 may be sequentially arranged over the inter-insulating layer 107. Each of the first organic insulating layer 109 and the second organic insulating layer 111 may include a contact hole overlapping the drain electrode DE. A connection metal 110 may be disposed over the first organic insulating layer 109. The connection metal 110 may be connected to the drain electrode DE through a contact hole defined in the first organic insulating layer 109.

Each of the first organic insulating layer 109 and the second organic insulating layer 111 may include an organic insulating material such as a general-purpose polymer such as benzocyclobutene, polyimide, hexamethyldisiloxane, polymethylmethacrylate, or polystyrene, a polymer derivative having a phenol-based group, an acrylic polymer, an imide-based polymer, an aryl ether-based polymer, an amide-based polymer, a fluorine-based polymer, a p-xylene-based polymer, or a vinyl alcohol-based polymer and may have a single-layer structure or a multilayer structure.

The organic light-emitting diode OLED may be disposed over the second organic insulating layer 111. The organic light-emitting diode OLED may include a pixel electrode 210, an intermediate layer 220, and an opposite electrode 230.

The pixel electrode 210 may be disposed over the second organic insulating layer 111. The pixel electrode 210 may be connected to the connection metal (also referred to as a contact metal) 110 through a contact hole defined in the second organic insulating layer 111. The pixel electrode 210 may be connected to the drain electrode DE of the thin film transistor TFT through the contact metal 110.

In an embodiment, the pixel electrode 210 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any combinations thereof. However, the configuration and material of the pixel electrode 210 are not limited thereto and may be variously modified.

A pixel definition layer 113 may be disposed over the second organic insulating layer 111. The pixel definition layer 113 may cover the edge (or edge area) of the pixel electrode 210. In other words, the pixel definition layer 113 may be opened to expose a center portion of the pixel electrode 210. The size and shape of an emission area of the organic light-emitting diode OLED may be determined by the opening of the pixel definition layer 113.

The intermediate layer 220 may be disposed over the pixel electrode 210. The intermediate layer 220 may include a first functional layer 221 and a second functional layer 223 arranged over the pixel definition layer 113, and an emission layer 222 disposed in the opening of the pixel definition layer 113. In an embodiment, the first functional layer 221 may be disposed over the pixel definition layer 113, the emission layer 222 may be disposed in the opening of the pixel definition layer 113 over the first functional layer 221, and the second functional layer 223 may be disposed over the first functional layer 221 to cover the emission layer 222. In other words, the emission layer 222 may be disposed in the opening of the pixel definition layer 113 and may be disposed between the first and second functional layers 221 and 223.

The emission layer 222 may include an organic emission layer including a low-molecular weight or high-molecular weight material. The first functional layer 221 may include an electron transport layer (“ETL”) and/or an electron injection layer (“EIL”). The second functional layer 223 may include a hole transport layer (“HTL”) and/or a hole injection layer (“HIL”). In an embodiment, the first functional layer 221 or the second functional layer 223 may be omitted. In an embodiment, the positions of the first functional layer 221 and the second functional layer 223 may be interchanged with each other.

The opposite electrode 230 may be disposed over the intermediate layer 220. In an embodiment, the opposite electrode 230 may be disposed over the second functional layer 223, for example. The opposite electrode 230 may be disposed to cover an entirety of the intermediate layer 220. In an embodiment, the opposite electrode 230 may include a conductive material having a relatively low work function. In an embodiment, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (“IR”), chromium (Cr), lithium (Li), calcium (Ca), or any alloy thereof, for example. In an alternative embodiment, the opposite electrode 230 may further include a layer such as ITO, IZO, ZnO, or In₂O₃ over the (semi) transparent layer including the above material.

A capping layer 240 may be disposed over the opposite electrode 230. The capping layer 240 may have a lower refractive index than the opposite electrode 230 and may improve light efficiency by reducing the proportion of light that is not emitted to the outside by being totally reflected after being generated in the intermediate layer 220. In an embodiment, the capping layer 240 may be omitted.

The capping layer 240 may be an organic capping layer including an organic material, an inorganic capping layer including an inorganic material, or a composite capping layer including an organic material and an inorganic material. In an embodiment, the capping layer 240 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combinations thereof, for example. In an alternative embodiment, the capping layer 240 may include an inorganic material such as zinc oxide (ZnO₂), titanium oxide (TiO₂), zirconium oxide (ZrO₂), nitrogen oxide (NO), niobium oxide (Nb₂O₅), tantalum oxide (Ta₂O₅), tin oxide (SnO₂), nickel oxide (NiO), indium nitride (InN), and gallium nitride (GaN). However, the material of the capping layer 240 is not limited thereto, and the capping layer 240 may include various materials.

The encapsulation layer 300 may be disposed over the capping layer 240. The encapsulation layer 300 may include at least one inorganic layer and at least one organic layer. In an embodiment, the encapsulation layer 300 may include first and second inorganic encapsulation layers 310 and 330 and an organic encapsulation layer 320 therebetween. Each of the first and second inorganic encapsulation layers 310 and 330 may include one or more inorganic insulating materials such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 320 may include a polymer-based material. The polymer-based material may include silicon-based resin, acryl-based resin, epoxy-based resin, polyimide, polyethylene, or the like.

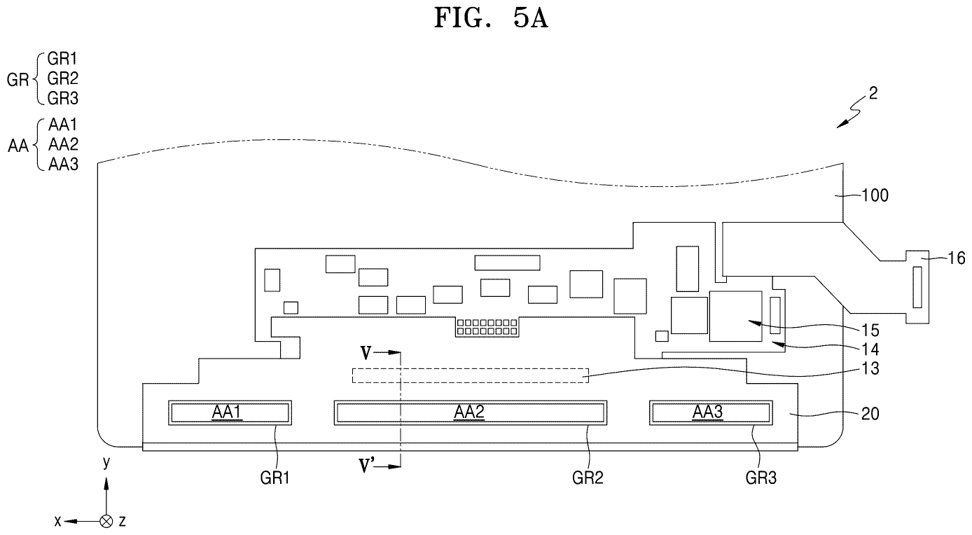

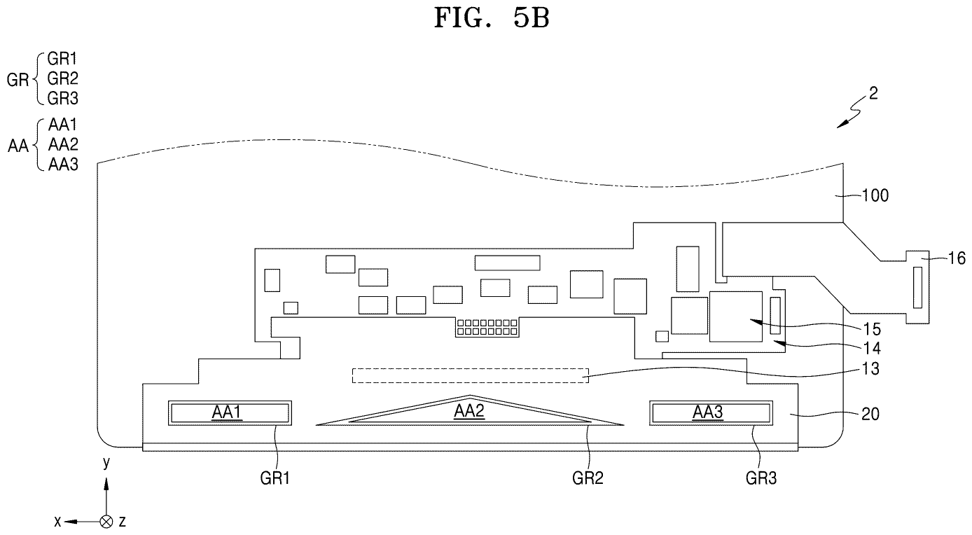

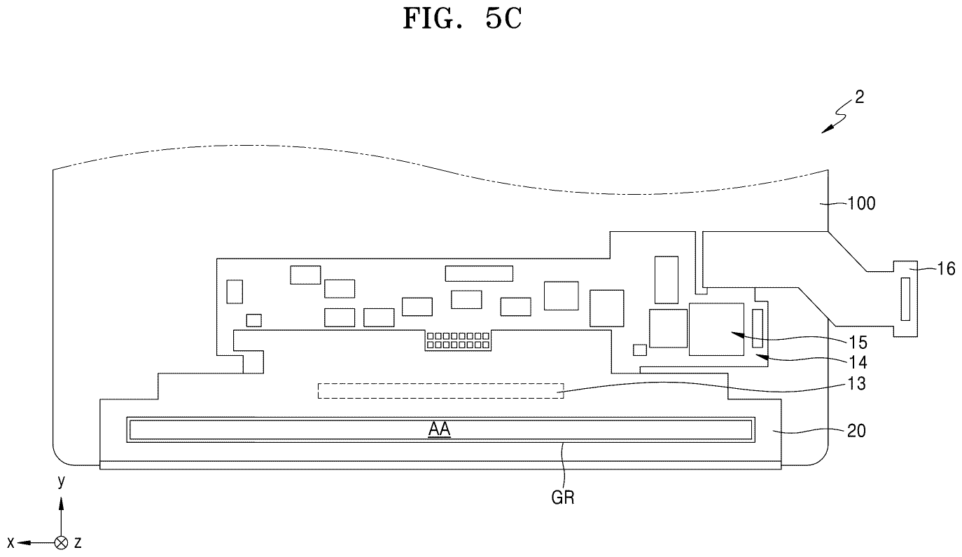

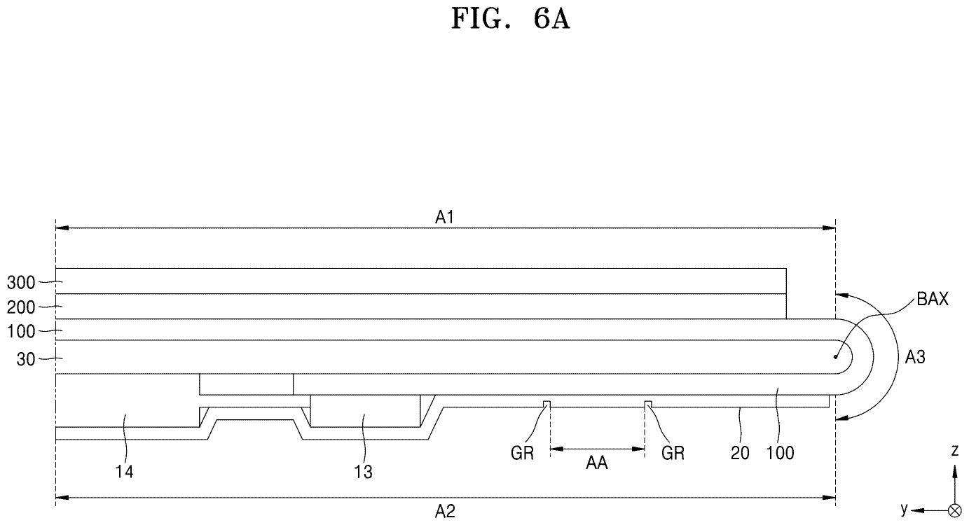

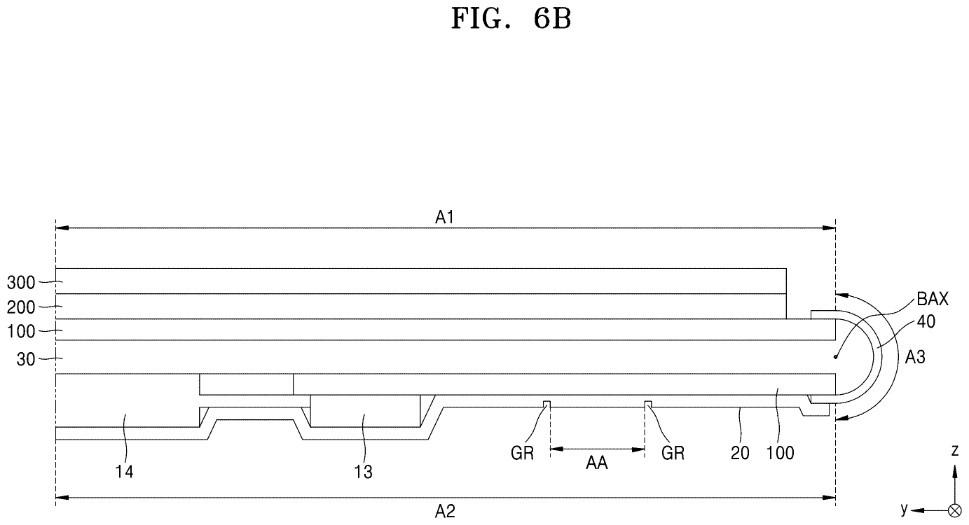

FIGS. 5A, 5B, and 5C are bottom views of a display panel 2 according to various embodiments. FIGS. 6A and 6B are cross-sectional views of a display panel 2 according to various embodiments.

FIGS. 6A and 6B may be cross-sectional views of the display panel 2 taken along line V-V′ of FIG. 5A, for example. FIGS. 5A, 5B, 50, 6A, and 6B illustrate an embodiment in which the display panel 2 is bent.

Referring to FIGS. 5A, 5B, 5C, 6A, and 6B, the display panel 2 may be bent at a portion. In an embodiment, the display panel 2 may be bent around a bending axis BAX in a third area A3, for example. Accordingly, a second area A2 of the display panel 2 may be disposed in the −z direction of a first area A1 of the display panel 2. A second portion of the substrate 100 corresponding to the second area A2 may be disposed in the −z direction of a first portion of the substrate 100 corresponding to the first area A1. A shock absorbing layer 30 may be disposed between the first portion and the second portion of the substrate 100.

In an embodiment, as illustrated in FIG. 6A, a portion (e.g., the third portion) of the substrate 100 may be bent in the third area A3. The third portion of the substrate 100 may correspond to the third area A3 and may connect the first portion and the second portion of the substrate 100.

In an embodiment, as illustrated in FIG. 6B, a connection portion 40 may be disposed in the third area A3 and may be bent to connect the first area A1 and the second area A2. In an embodiment, the connection portion 40 may connect the first portion and the second portion of the substrate 100, for example.

Herein, the expression ‘disposed over’ may have different meanings depending on the area of the display panel 2 that is a subject of description.

In describing the first area A1 of the display panel 2, the expression ‘disposed over’ may be understood as ‘disposed in the +z direction’. In an embodiment, in the first area A1, a display element layer 200 may be disposed over the substrate 100, and an encapsulation layer 300 may be disposed over the display element layer 200, for example. That is, in the first area A1, the display element layer 200 may be disposed in the +Z direction of the substrate 100, and the encapsulation layer 300 may be disposed in the +z direction of the display element layer 200.

In describing the second area A1 of the display panel 2, the expression ‘disposed over’ may be understood as ‘disposed in the −z direction’. In an embodiment, in the second area A1, a driving circuit chip 13 may be disposed over the substrate 100, and a cover film 20 may be disposed over the driving circuit chip 13, for example. That is, in the second area A2, the driving circuit chip 13 may be disposed in the −z direction of the substrate 100, and the cover film 20 may be disposed in the −z direction of the driving circuit chip 13.

Similarly, in the second area A2, a printed circuit board 14 may be disposed over the shock absorbing layer 30, and a portion of the printed circuit board 14 may be disposed over the substrate 100. That is, in the second area A2, the printed circuit board 14 may be disposed in the −z direction of the shock absorbing layer 30, and a portion of the printed circuit board 14 may be disposed in the −z direction of the substrate 100. The printed circuit board 14 may be connected to the driving circuit chip 13 in the second area A2.

The cover film 20 may cover the driving circuit chip 13 and may cover a portion of the printed circuit board 14. In an embodiment, the printed circuit board 14 may include a plurality of electronic components 15 disposed (e.g., mounted) on the printed circuit board 14. In an embodiment, the printed circuit board 14 may include a sensor driver 16 connected to one side of the printed circuit board 14. The cover film 20 may not cover the plurality of electronic components 15 and the sensor driver 16. That is, the cover film 20 may cover an entirety of the driving circuit chip 13 and may partially cover the printed circuit board 14.

At least one groove GR may be defined in the cover film 20. The cover film 20 may be disposed in the second area A2. The groove GR of the cover film 20 may also be defined in the second area A2. The groove GR of the cover film 20 may be defined in the −y direction of the driving circuit chip 13. In other words, the groove GR of the cover film 20 may be defined between the driving circuit chip 13 and the third area A3.

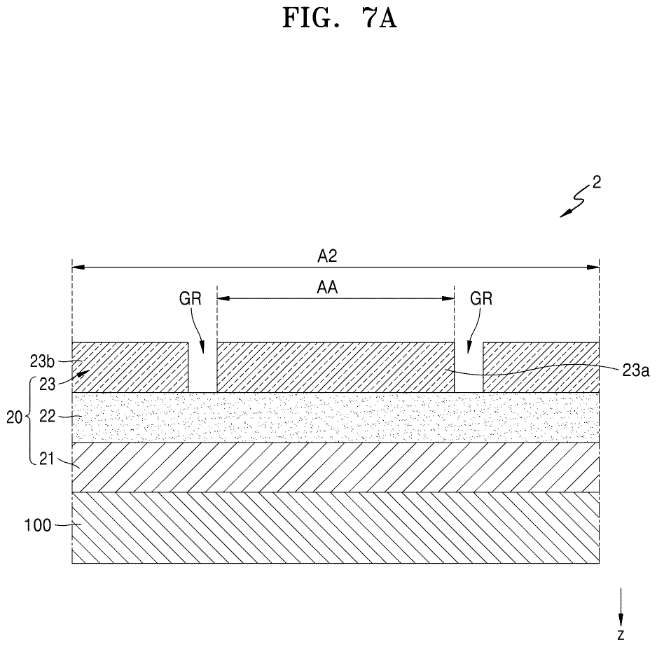

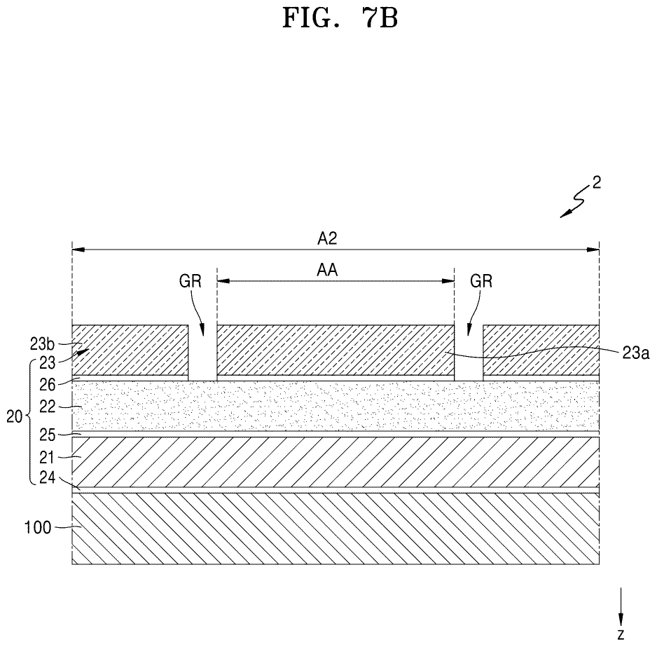

In an embodiment, the groove GR of the cover film 20 may be defined over a portion of the cover film 20 in the thickness direction (e.g., ±z direction) of the cover film 20. In other words, the groove GR of the cover film 20 may be a blind hole. In other words, the groove GR of the cover film 20 may not pass through the cover film 20. The ±z direction structure of the groove GR of the cover film 20 will be described below with reference to FIGS. 7A and 7B.

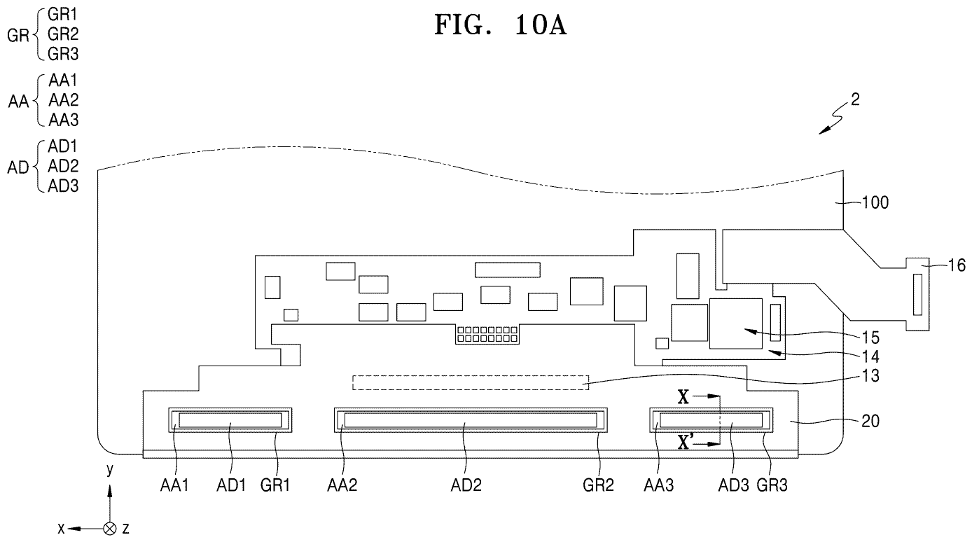

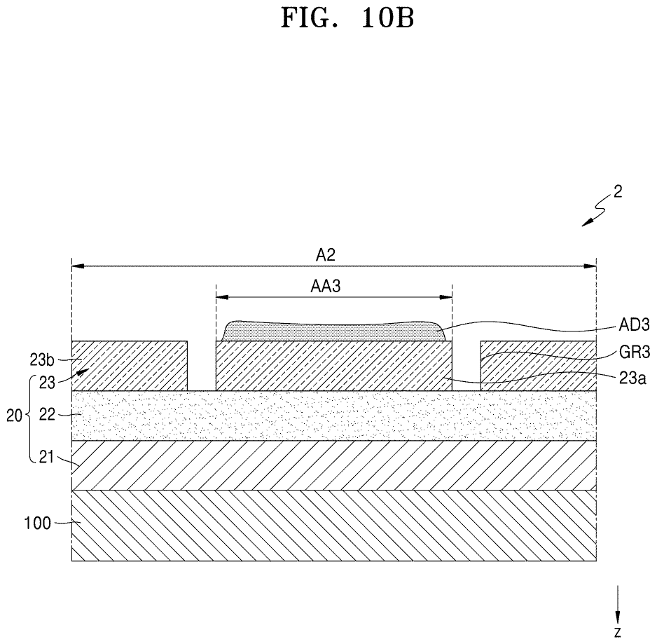

In an embodiment, the groove GR of the cover film 20 may be provided in a closed-loop shape. In an embodiment, the closed-loop shape of the groove GR of the cover film 20 may define at least one adhesive area AA. In other words, an area surrounded by the closed-loop shape of the groove GR of the cover film 20 may be defined as an adhesive area AA. The adhesive area AA may be an area in which an adhesive AD (refer to FIG. 10A) described below is disposed.

In an embodiment, as illustrated in FIG. 5C, the groove GR of the cover film 20 may be provided in the shape of a generally tetragonal (e.g., rectangular) frame with a ±x direction length greater than a ±y direction length. The adhesive area AA defined by the groove GR may be provided in a tetragonal (e.g., rectangular) shape with a ±x direction length greater than a ±y direction length.

The groove GR and the adhesive area AA may be provided as one groove GR and one adhesive area AA as illustrated in FIG. 5C or may be provided as a plurality of grooves GR and a plurality of adhesive areas AA as illustrated in FIGS. 5A and 5B.

In an embodiment, the plurality of grooves GR may include a first groove GR1, a second groove GR2, and a third groove GR3. Each of the first groove GR1, the second groove GR2, and the third groove GR3 may be provided in a closed-loop shape. The first groove GR1, the second groove GR2, and the third groove GR3 may be defined apart from each other. In an embodiment, the first groove GR1, the second groove GR2, and the third groove GR3 may be defined in the ±x direction. In an embodiment, the first groove GR1 may be defined in the −x direction of the second groove GR2, and the third groove GR3 may be defined in the +x direction of the second groove GR2, for example.

In an embodiment, the shape and/or size of one of the plurality of grooves GR may be different from the shape and/or size of another one of the plurality of grooves GR.

In an embodiment, the shapes and sizes of the first groove GR1 and the third groove GR3 may be equal to each other. In an embodiment, both the first groove GR1 and the third groove GR3 may be provided in the shape of a tetragonal (e.g., quadrangular, e.g., rectangular) frame with a ±x direction length greater than a ±y direction length and may have the same size, for example.

In an embodiment, as illustrated in FIG. 5A, the shape of the second groove GR2 may be generally similar to the shape of the first groove GR1 and the third groove GR3, and the size of the second groove GR2 may be different from the size of the first groove GR1 and the third groove GR3. In an embodiment, all of the first groove GR1, the second groove GR2, and the third groove GR3 may be provided in the shape of a tetragonal (e.g., quadrangular, e.g., rectangular) frame with a ±x-direction length greater than a ±y-direction length, for example. The ±x-direction length of the second groove GR2 may be greater than the ±x-direction length of the first groove GR1 or the third groove GR3. Moreover, the ±y-direction lengths of the first groove GR1, the second groove GR2, and the third groove GR3 may be equal to each other.

In an embodiment, as illustrated in FIG. 5B, the shape of the second groove GR2 may be different from the shape of the first groove GR1 and the third groove GR3. In an embodiment, the first groove GR1 and the third groove GR3 may be provided in the shape of a tetragonal (e.g., quadrangular, e.g., rectangular) frame with a ±x direction length greater than a ±y direction length, for example. The second groove GR2 may be provided in the shape of a triangular (e.g., isosceles triangular) frame with a ±x direction length greater than a ±y direction length.

The first groove GR1 may define a first adhesive area AA1, the second groove GR2 may define a second adhesive area AA2, and the third groove GR3 may define a third adhesive area AA3. The characteristics of the shape of each adhesive area AA may be similar to the characteristics of the shape of the corresponding groove GR.

In an embodiment, similarly to the first groove GR1 and the second groove GR2, the first adhesive area AA1 and the second adhesive area AA2 may have the same shape and size.

In an embodiment, as illustrated in FIG. 5A, the shape of the second adhesive area AA2 may be generally similar to the shape of the first adhesive area AA1 and the third adhesive area AA3, and the size of the second adhesive area AA2 may be different from the size of the first adhesive area AA1 and the third adhesive area AA3. In an embodiment, all of the first adhesive area AA1, the second adhesive area AA2, and the third adhesive area AA3 may be provided in a tetragonal (e.g., quadrangular, e.g., rectangular) shape with a ±x direction length greater than a ±y direction length, for example. The ±x direction length of the second adhesive area AA2 may be greater than the ±x direction length of the first adhesive area AA1 or the third adhesive area AA3. Moreover, the ±y direction lengths of the first adhesive area AA1, the second adhesive area AA2, and the third adhesive area AA3 may be equal to each other.

In an embodiment, as illustrated in FIG. 5B, the shape of the second adhesive area AA2 may be different from the shape of the first adhesive area AA1 and the third adhesive area AA3. In an embodiment, the first adhesive area AA1 and the third adhesive area AA3 may be provided in a tetragonal (e.g., rectangular) shape with a ±x direction length greater than a ±y direction length, for example. The second adhesive area AA2 may be provided in a triangular (e.g., isosceles triangular) shape with a ±x direction length greater than a ±y direction length.

FIGS. 7A and 7B are cross-sectional views of a portion of a display panel 2 according to various embodiments.

Referring to FIGS. 7A and 7B, a cover film 20 may include a plurality of layers. A groove GR of the cover film 20 may be defined over one of the plurality of layers of the cover film 20.

In an embodiment, the cover film 20 may include a first layer 21, a second layer 22, and a third layer 23. The first layer 21 may be disposed over a substrate 100. The second layer 22 may be disposed over the first layer 21. The third layer 23 may be disposed over the second layer 22. Also, because the cover film 20 may be disposed in the second area A2 of the display panel 2, it may be understood that the first layer 21 of the cover film 20 is disposed in the −z direction of the substrate 100. Similarly, it may be understood that the second layer 22 is disposed in the −z direction of the first layer 21 and the third layer 23 is disposed in the −z direction of the second layer 22.

In an embodiment, the groove GR of the cover film 20 may be defined in the third layer 23 of the cover film 20. In an embodiment, the groove GR may pass through the third layer 23. In other words, the groove GR may be defined throughout the third layer 23 in the thickness direction (e.g., +z direction) of the cover film 20. In other words, when viewed based on the third layer 23, the groove GR may be provided as a through hole.

In an embodiment, an adhesive area AA may be defined by the groove GR of the cover film 20. The third layer 23 of the cover film 20 may include a first portion 23a corresponding to the adhesive area AA and a second portion 23b outside the adhesive area AA and the groove GR. A first portion 23a and a second portion 23b of the third layer 23 may be spaced apart from each other by the groove GR.

In an embodiment, as illustrated in FIG. 7B, the cover film 20 may further include first to third adhesive layers 24, 25, and 26. The first adhesive layer 24 may be disposed between the substrate 100 and the first layer 21 of the cover film 20. The second adhesive layer 25 may be disposed between the first and second layers 21 and 22 of the cover film 20. The third adhesive layer 26 may be disposed between the second and third layers 22 and 23 of the cover film 20. The groove GR of the cover film 20 may be defined through the third adhesive layer 26.

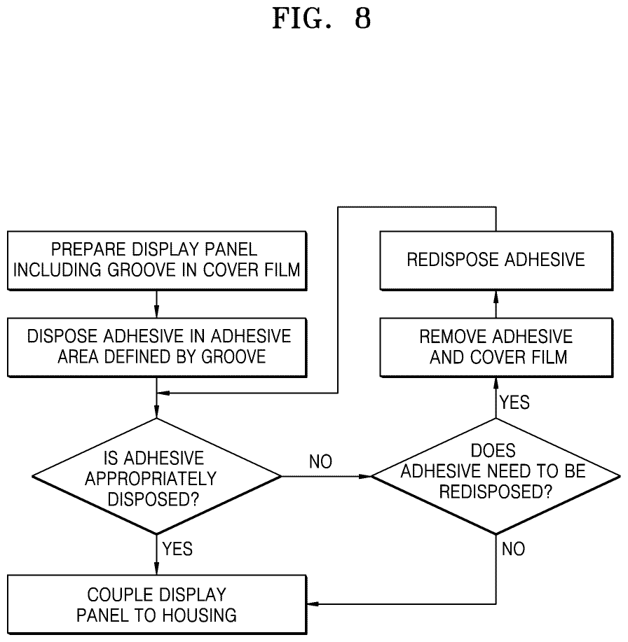

FIG. 8 is a flowchart illustrating an embodiment of processes of an electronic apparatus manufacturing method.

Referring to FIG. 8, a process of coupling a display panel 2 and a housing 3 among the processes of an electronic apparatus manufacturing method will be described.

First, a display panel 2 defining a groove GR in a cover film 20 may be prepared. The structure of the display panel 2 may be as described above.

Thereafter, an adhesive AD may be disposed in an adhesive area AA defined by the groove GR.

Thereafter, it may be determined whether the adhesive AD is normally disposed.

When the adhesive AD is normally disposed in the adhesive area AA, the display panel 2 with the adhesive AD disposed thereon may be coupled (e.g., adhered) to the housing 3.

When the adhesive AD is not normally disposed in the adhesive area AA, e.g., when the adhesive AD is overapplied or misapplied, it may be determined whether the adhesive AD needs to be rearranged.

When it is determined that the adhesive AD is not normally disposed but does not need to be rearranged, the display panel 2 may be coupled (e.g., adhered) to the housing 3.

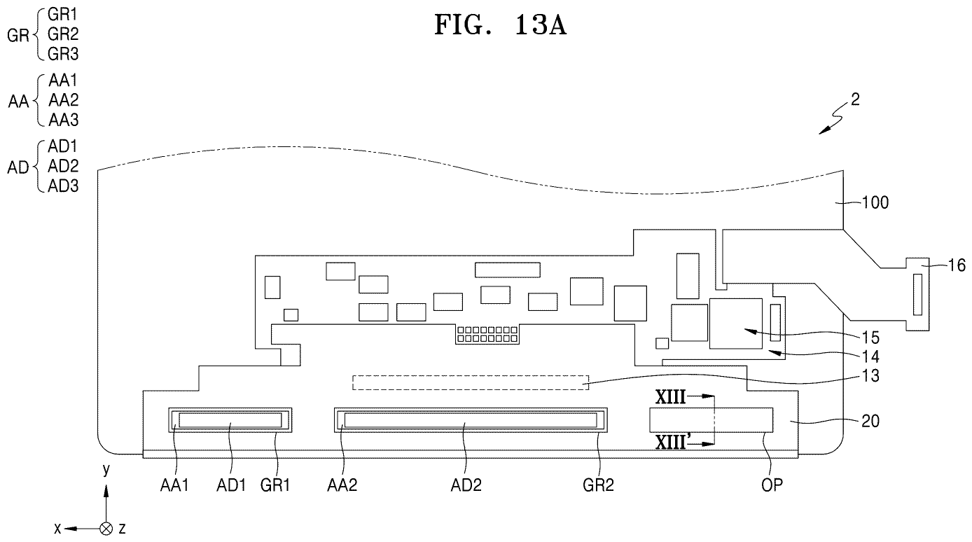

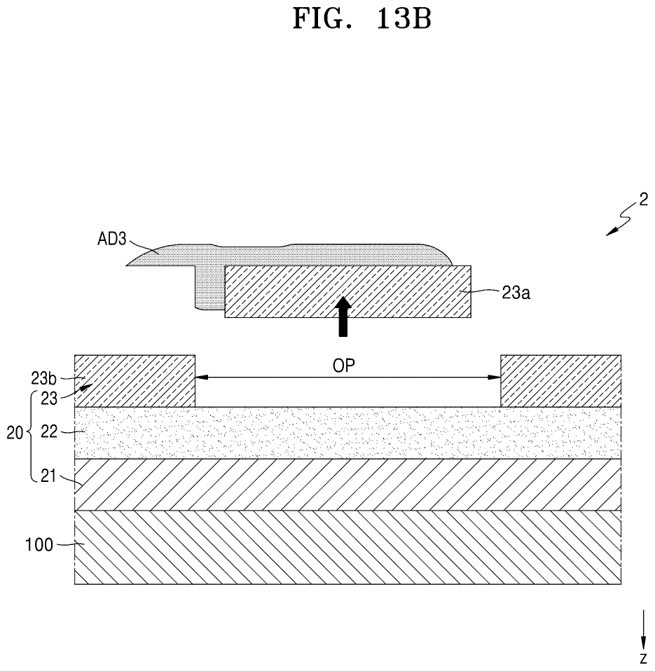

When it is determined that the adhesive AD is not normally disposed and needs to be rearranged, a misarranged adhesive AD3 (refer to FIG. 13B) and a first portion 23a of the cover film 20 corresponding thereto may be removed together.

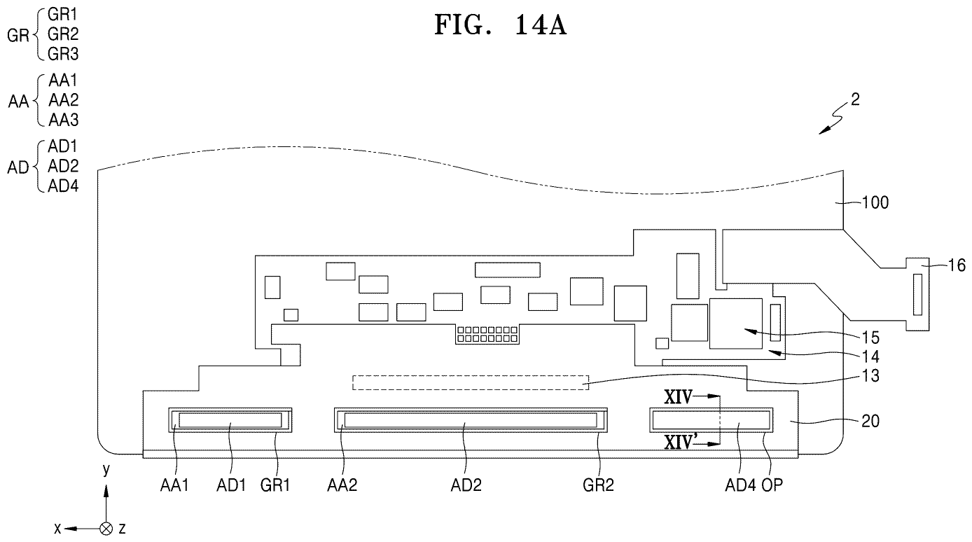

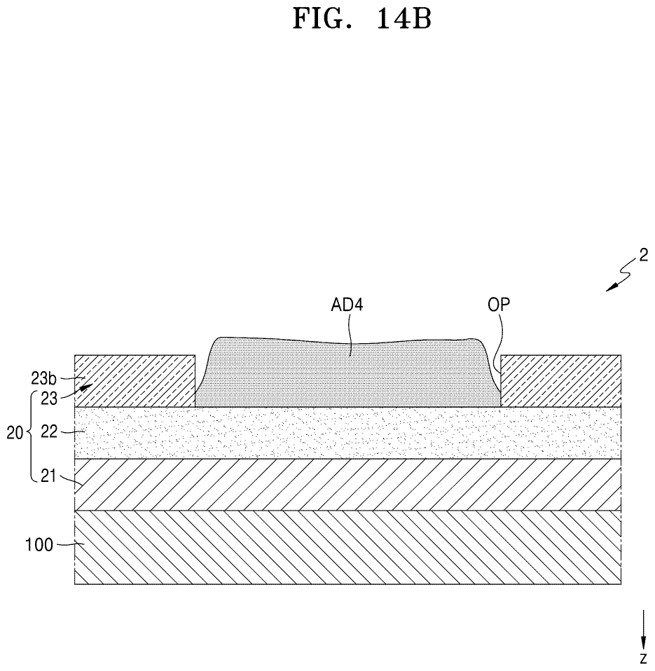

Thereafter, an adhesive AD4 (refer to FIG. 14B) may be rearranged, and whether the adhesive AD4 is normally disposed may be determined again.

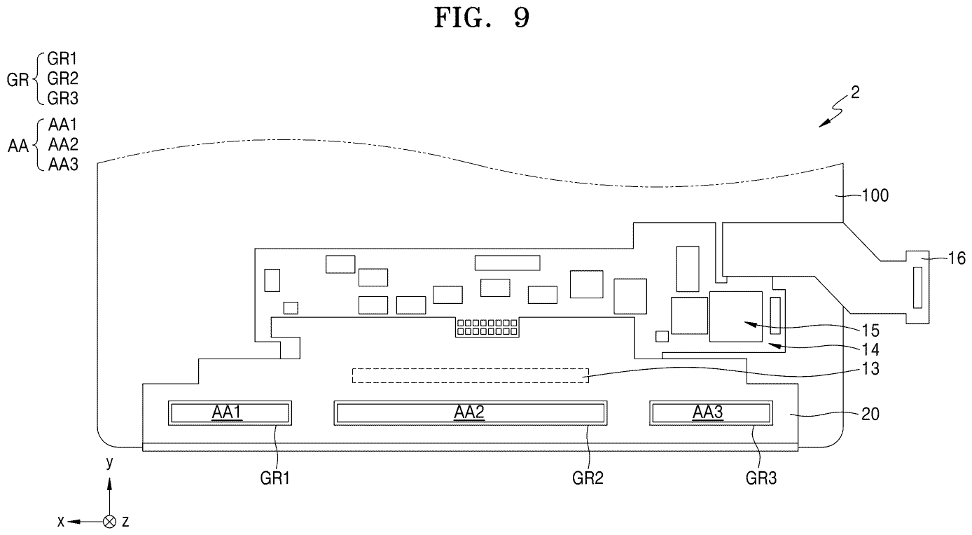

The process of coupling the display panel 2 and the housing 3 may be performed through the above processes. The above processes will be described below in detail with reference to FIGS. 9 to 14B.

FIG. 9 is a bottom view schematically illustrating an embodiment of a process of an electronic apparatus manufacturing method.

Referring to FIGS. 8 and 9, a display panel 2 defining at least one groove GR and an adhesive area AA in a cover film 20 may be prepared. The features of the display panel 2 may be as described above. In the illustrated embodiment, the display panel 2 illustrated in FIG. 5A will be described as an example. However, the method according to the disclosure is not necessarily limited thereto, and embodiments in which grooves GR and adhesive areas AA of other types are defined may also fall within the scope of the disclosure.

In the illustrated embodiment, the display panel 2 may be prepared in a bent state, and the bent shape of the display panel 2 may be as described above. In an alternative embodiment, the method according to the disclosure may be understood as further including a process of bending the display panel 2 as a previous process of the process illustrated in FIG. 9. In this case, the bent shape of the display panel 2 may be as described above.

The grooves GR of the cover film 20 may include first to third grooves GR1, GR2, and GR3. Each of the first to third grooves GR1, GR2, and GR3 may be provided in a closed-loop shape. The closed-loop shapes of the first to third grooves GR1, GR2, and GR3 may respectively define (or partition) first to third adhesive areas AA1, AA2, and AA3.

FIG. 10A is a bottom view schematically illustrating an embodiment of a process of an electronic apparatus manufacturing method. FIG. 10B is a cross-sectional view of the display panel 2 taken along line X-X′ of FIG. 10A. FIGS. 10A and 10B illustrate an embodiment in which the adhesive AD is normally disposed.

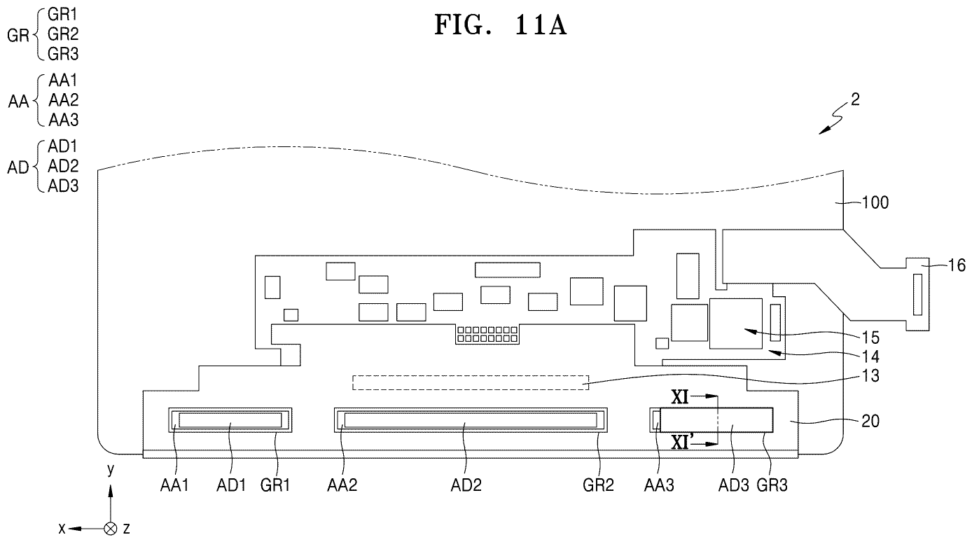

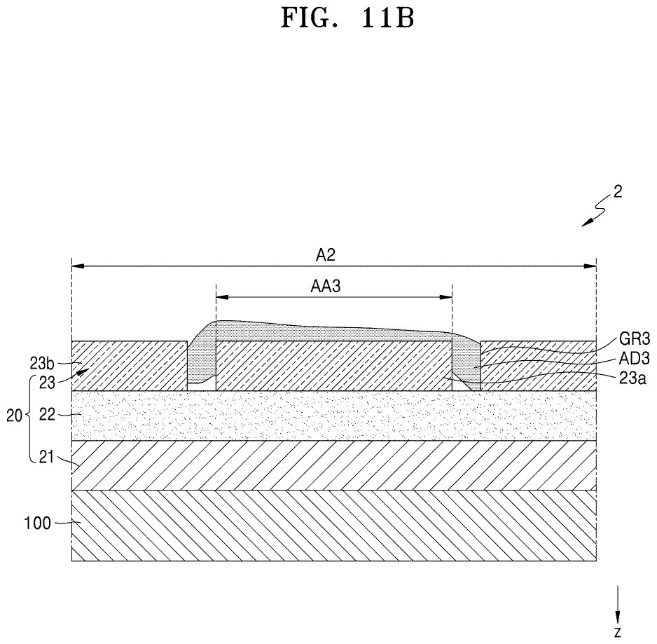

FIG. 11A is a bottom view schematically illustrating an embodiment of a process of an electronic apparatus manufacturing method. FIG. 11B is a cross-sectional view of the display panel 2 taken along line XI-XI′ of FIG. 11A. FIGS. 11A and 11B illustrate an embodiment in which a portion of the adhesive AD is misarranged (e.g., overapplied).

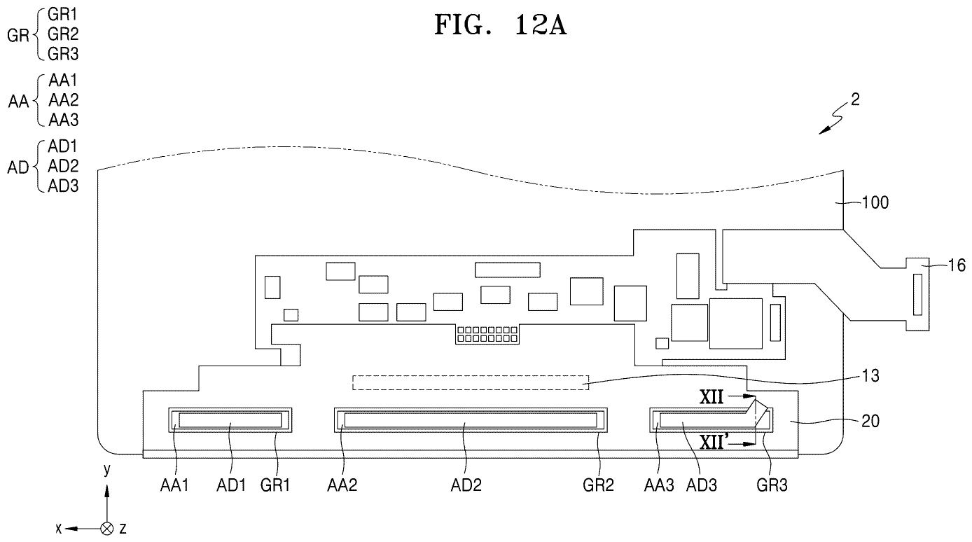

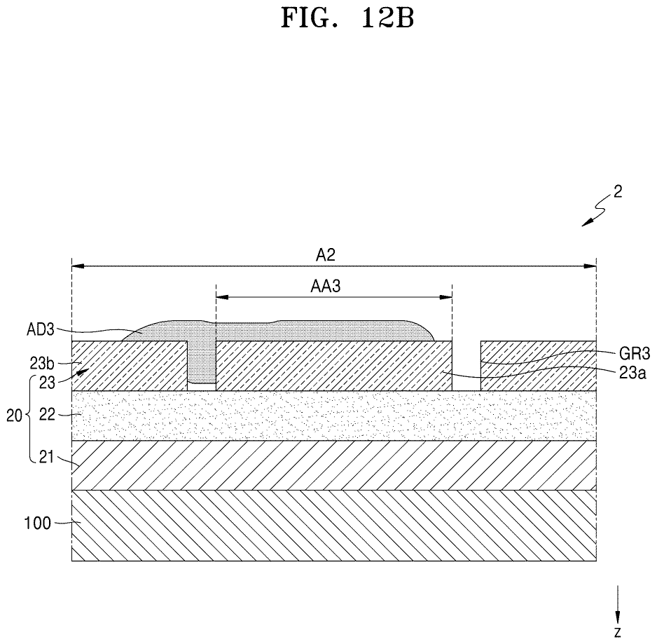

FIG. 12A is a bottom view schematically illustrating an embodiment of a process of an electronic apparatus manufacturing method. FIG. 12B is a cross-sectional view of the display panel 2 taken along line XII-XII′ of FIG. 12A. FIGS. 12A and 12B illustrate an embodiment in which a portion of the adhesive AD is misarranged (e.g., misapplied).

Referring to FIGS. 10A to 12B together with FIG. 8, an adhesive AD may be disposed in an adhesive area AA defined by a groove GR of a cover film 20. The groove GR may include first to third grooves GR1, GR2, and GR3, the adhesive area AA may include first to third adhesive areas AA1, AA2, and AA3, and the adhesive AD may include first to third adhesives AD1, AD2, and AD3. In an embodiment, the first adhesive AD1 may be disposed in the first adhesive area AA1, the second adhesive AD2 may be disposed in the second adhesive area AA2, and the third adhesive AD3 may be disposed in the third adhesive area AA3.

The adhesive AD may be disposed over a portion of the third layer 23 of the cover film 20 corresponding to the adhesive area AA. In an embodiment, as illustrated in FIG. 10B, the third adhesive AD3 may be disposed over a first portion 23a of the third layer 23 corresponding to the third adhesive area AA3, for example.

After the adhesive AD is disposed, it may be determined whether the adhesive AD is normally disposed. The normally disposed adhesive AD may be disposed in the adhesive area AA corresponding thereto. In an embodiment, when the adhesive AD is normally disposed, the first adhesive AD1 may be disposed in the first adhesive area AA1, the second adhesive AD2 may be disposed in the second adhesive area AA2, and the third adhesive AD3 may be disposed in the third adhesive area AA3, for example.

In other words, when viewed in one direction (e.g., the −z direction), the area of the normally disposed adhesive AD may be less than the area of the adhesive area AA. In an embodiment, when the adhesive AD is normally disposed, the area of the first adhesive AD1 may be less than the area of the first adhesive area AA1, the area of the second adhesive AD2 may be less than the area of the second adhesive area AA2, and the area of the third adhesive AD3 may be less than the area of the third adhesive area AA3, for example.

Thus, in the embodiment illustrated in FIGS. 10A to 12B, the first adhesive AD1 and the second adhesive AD2 may be considered as being normally disposed.

FIGS. 10A and 10B illustrate an embodiment in which all of the first adhesive AD1, the second adhesive AD2, and the third adhesive AD3 are normally disposed.

Referring to FIGS. 10A and 10B, the third adhesive AD3 may be disposed over the first portion 23a of the third layer 23 of the cover film 20 and may be disposed in the third adhesive area AA3. Although not illustrated, the first adhesive AD1 and the second adhesive AD2 may also be arranged over the cover film 20 similarly to the third adhesive AD3 illustrated in FIG. 10B.

Referring also to FIG. 8, in the case of the illustrated embodiment, because the adhesive AD is normally disposed, the display panel 2 may be coupled (e.g., adhered) to the housing 3.

FIGS. 11A and 11B illustrate an embodiment in which the first adhesive AD1 and the second adhesive AD2 are normally arranged and the third adhesive AD3 are misarranged (e.g., overapplied). However, the misarrangement of the third adhesive AD3 is just an example, and the method of the disclosure may be similarly applied even when any other adhesive is misarranged.

Referring to FIGS. 11A and 11B, the third adhesive AD3 may be disposed beyond the third adhesive area AA3. In other words, the third adhesive AD3 may be disposed beyond the edge of the first portion 23a of the third layer 23 of the cover film 20. In the illustrated embodiment, the position at which the third adhesive AD3 is disposed may be normal. However, such a phenomenon may occur when the third adhesive AD3 with fluidity flows due to an external impact between the processes or when the third adhesive AD3 is over-arranged.

A portion of the third adhesive AD3 may be disposed in the third groove GR3. The third adhesive AD3 may contact the side surface of the third layer 23 of the cover film 20 defining the third groove GR3. In an embodiment, the third adhesive AD3 may contact the side surface of the first portion 23a and the side surface of the second portion 23b of the third layer 23, for example. In an embodiment, the third adhesive AD3 may contact the upper surface of the second layer 22 of the cover film 20. In an embodiment, the third adhesive AD3 may have viscosity, and even when the third adhesive AD3 flows into the third groove GR3, it may not completely fill the third groove GR3. Accordingly, a space may exist between the third adhesive AD3 and the second layer 22 of the cover film 20.

Moreover, the third adhesive AD3 may not be disposed beyond the third groove GR3. In an embodiment, the third adhesive AD3 may not be disposed over the second portion 23b of the third layer 23 of the cover film 20, for example. In other words, the third adhesive AD3 may be disposed in the third adhesive area AA3 or the third groove GR3.

In summary, when the arrangement position of the adhesive AD itself is normal but the adhesive AD flows beyond the adhesive area AA due to an external impact or overapplication, the groove GR may function as a trench that prevents the overflow of the adhesive AD by accommodating a portion of the adhesive AD.

Referring to FIG. 8 together, in the case of the illustrated embodiment, it may be determined whether a portion of the adhesive AD (e.g., the third adhesive AD3) is abnormally disposed and thus desired to be rearranged. However, in the case of the illustrated embodiment, because the groove GR has prevented an overflow, it may be determined that the adhesive does not need to be rearranged because it does not cause a defect even when it is coupled to the housing 3 as it is. Thus, in the case of the illustrated embodiment, the display panel 2 may be coupled (e.g., adhered) to the housing 3.

By providing the groove GR as described above, it will be possible to reduce cases where the display panel 2 should be discarded due to a minor error (e.g., overapplication) that occurs during the arrangement of the adhesive AD.

FIGS. 12A and 12B illustrate an embodiment in which the first adhesive AD1 and the second adhesive AD2 are normally disposed and the third adhesive AD3 are misarranged (e.g., misapplied). However, the misarrangement of the third adhesive AD3 is just an example, and the method of the disclosure may be similarly applied even when any other adhesive is misarranged.

Referring to FIGS. 12A and 12B, the third adhesive AD3 may be disposed beyond the third adhesive area AA3. Also, a portion of the third adhesive AD3 may be disposed beyond the third groove GR3. In other words, a portion of the third adhesive AD3 may be disposed over the second portion 23b of the third layer 23 of the cover film 20. In the illustrated embodiment, the arrangement position and/or shape of the third adhesive AD3 may be incorrect, and thus a portion of the third adhesive AD3 may be disposed outside the third adhesive area AA3 and the third groove GR3.

Referring to FIG. 8 together, in a case like the illustrated embodiment, a defect may occur when a portion of the adhesive AD (e.g., the third adhesive AD3) is abnormally disposed and the display panel 2 is coupled to the housing 3 as it is. Thus, the adhesive AD may need to be rearranged.

FIG. 13A is a bottom view schematically illustrating an embodiment of a process of an electronic apparatus manufacturing method. FIG. 13B is a cross-sectional view of the display panel 2 taken along line XIII-XIII′ of FIG. 13A.

Referring to FIGS. 13A an 13B together with FIG. 8, a misarranged adhesive AD may be removed together with a portion of the cover film 20 corresponding thereto. In an embodiment, the third adhesive AD3 may be removed together with the first portion 23a of the third layer 23 of the cover film 20, for example.

It may be difficult to remove only the third adhesive AD3 separately. For example, the third adhesive AD3 may be cured through heat or light and then separated from the cover film 20, but in this case, the first adhesive AD1 or the second adhesive AD2 may also be cured, thus making it difficult to realize a subsequent coupling process with the housing 3. In the case of the uncured third adhesive AD3, because it may have fluidity and viscosity and a portion thereof may be arranged in the third groove GR3 (refer to FIG. 12B), it may be difficult to remove only the third adhesive AD3.

In the case of the method according to the disclosure, the above problems may be easily solved by removing the first portion 23a of the third layer 23 of the cover film 20 together with the third adhesive AD3. Because the first portion 23a of the third layer 23 is spaced apart from the second portion 23b by the third groove GR3, the first portion 23a of the third layer 23 may be removed only by an external force without going through a separate process. In this case, the third adhesive AD3 disposed over the first portion 23a of the third layer 23 may also be removed together. In this case, a portion of the third adhesive AD3 may be disposed in the third groove GR3 (refer to FIG. 12B) and a portion thereof may be disposed over the second portion 23b of the third layer 23. However, because the third adhesive AD3 may have viscosity, when the first portion 23a of the third layer 23 is removed with sufficient care, the third adhesive AD3 may also be removed together.

As the first portion 23a of the third layer 23 of the cover film 20 is removed, an opening OP may be defined in the third layer 23. The opening OP may be a space in which the first portion 23a has been disposed and a space in which the third groove GR3 (refer to FIG. 12B) has been defined. The opening OP may be surrounded by the second portion 23b of the third layer 23.

FIG. 14A is a bottom view schematically illustrating an embodiment of a process of an electronic apparatus manufacturing method. FIG. 14B is a cross-sectional view of the display panel 2 taken along line XIV-XIV′ of FIG. 14A.

Referring to FIG. 14A and FIG. 14B together with FIG. 8, a new adhesive AD may be disposed in an area from which the misarranged adhesive AD has been removed. In an embodiment, a fourth adhesive AD4 may be disposed in the opening OP of the third layer 23 of the cover film 20 formed after removing the misarranged third adhesive AD3 (refer to FIG. 13B), for example.

The fourth adhesive AD4 may completely or partially fill the opening OP of the third layer 23. The upper surface of the fourth adhesive AD4 may protrude beyond the upper surface of the third layer 23. When the upper surface of the fourth adhesive AD4 does not protrude beyond the upper surface of the third layer 23, the fourth adhesive AD4 may not contact the housing 3 when the display panel 2 is coupled to the housing 3 in a subsequent process.

The fourth adhesive AD4 may not be disposed beyond the opening OP. In an embodiment, the fourth adhesive AD4 may not be disposed over the second portion 23b of the third layer 23, for example. In other words, the side surfaces of the third layer 23 defining the opening OP (e.g., the side surfaces of the second portion 23b) may function as a dam for preventing the overflow of the fourth adhesive AD4.

The amount of the fourth adhesive AD4 disposed in the opening OP may be suitably adjusted such that the upper surface of the fourth adhesive AD4 protrudes beyond the upper surface of the third layer 23 but the fourth adhesive AD4 does not overflow beyond the opening OP.

Thereafter, the display panel 2 may be coupled (e.g., adhered) to the housing 3.

Through the process described with reference to FIGS. 13A to 14B, even when the adhesive AD is misarranged, an opportunity may be provided to remove the misarranged adhesive AD (e.g., the third adhesive AD3) and arrange a new adhesive AD (e.g., the fourth adhesive AD4). This may reduce the number of cases where the display panel 2 needs to be discarded.

As described above, the display panel and the electronic apparatus manufacturing method using the display panel may reduce the need to discard the display panel and the housing when the adhesive is overapplied or misapplied to the display panel. In an embodiment, when the adhesive is overapplied, a portion of the overapplied adhesive may be disposed in the groove defined in the cover film to normally perform a coupling (e.g., to the housing). In another embodiment, when the adhesive is misapplied, the misapplied adhesive may be removed together with a portion of the cover film and the adhesive may be reapplied. This may help to increase the production efficiency of the electronic apparatus and reduce the production cost thereof.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate comprising a first area, a second area, and a bending area between the first area and the second area;
a driving circuit chip disposed in the second area of the substrate; and
a cover film disposed in the second area of the substrate and covering the driving circuit chip and defining at least one groove,
wherein the at least one groove of the cover film is defined in the second area and is defined over a portion of the cover film in a thickness direction of the cover film.

2. The display panel of claim 1, wherein the at least one groove is provided in a closed-loop shape.

3. The display panel of claim 2, wherein the closed-loop shape of the at least one groove defines at least one adhesive area.

4. The display panel of claim 2, wherein the at least one groove is provided in plural so that a plurality of grooves, each having the closed-loop shape, are spaced apart from each other.

5. The display panel of claim 4, wherein a shape of a groove of the plurality of grooves is different from a shape of another groove of the plurality of grooves.

6. The display panel of claim 1, wherein the cover film comprises a first layer, a second layer, and a third layer, and the at least one groove passes through the third layer.

7. The display panel of claim 6, wherein a first portion of the third layer of the cover film is spaced apart from a second portion of the third layer by the at least one groove.

8. The display panel of claim 6, wherein the cover film further comprises an adhesive layer between the second layer and the third layer, and the at least one groove passes through the third layer and the adhesive layer.

9. The display panel of claim 1, wherein the substrate is bent in the bending area, and
the second area of the substrate, the driving circuit chip, and the cover film are arranged under the first area of the substrate.

10. An electronic apparatus comprising:
a housing; and
a display panel coupled to the housing, the display panel comprising:
a substrate comprising a first area, a second area, and a bending area between the first area and the second area;
a driving circuit chip disposed in the second area of the substrate; and
a cover film disposed in the second area of the substrate and covering the driving circuit chip and defining at least one groove,
wherein the at least one groove of the cover film is defined in the second area and is defined over a portion of the cover film in a thickness direction of the cover film, and
the housing and the display panel are coupled through an adhesive disposed in an adhesive area defined by the at least one groove of the cover film of the display panel.

11. A method of manufacturing an electronic apparatus, the method comprising:
coupling a display panel to a housing, the display panel comprising:
a substrate comprising a first area, a second area, and a bending area between the first area and the second area;
a driving circuit chip disposed in the second area of the substrate; and
a cover film disposed in the second area of the substrate and covering the driving circuit chip and defining at least one groove,
wherein the at least one groove of the cover film is defined in the second area and is defined over a portion of the cover film in a thickness direction of the cover film, and
the process of coupling the display panel and the housing comprises a process of arranging an adhesive on the cover film of the display panel and adhering the display panel and the housing to each other.

12. The method of claim 11, wherein the at least one groove is provided in a closed-loop shape defining an adhesive area, and at least a portion of the adhesive is disposed in the adhesive area.

13. The method of claim 12, wherein the cover film comprises a first layer, a second layer, and a third layer and the at least one groove passes through the third layer, and
a first portion of the third layer corresponding to the adhesive area is spaced apart from a second portion of the third layer by the at least one groove.

14. The method of claim 13, wherein a portion of the adhesive is disposed over the first portion of the third layer, and another portion of the adhesive is disposed in the at least one groove beyond the first portion of the third layer.

15. The method of claim 14, further comprising removing the adhesive and the first portion of the third layer together.

16. The method of claim 15, further comprising arranging a new adhesive in an opening defined by removing the first portion of the third layer.

17. The method of claim 12, wherein the at least one groove defining the adhesive area is provided in plural so that a plurality of grooves having a plurality of closed-loop shapes define a plurality of adhesive areas spaced apart from each other.

18. The method of claim 17, wherein a closed-loop shape of a groove of the plurality of grooves is different from a closed-loop shape of another groove of the plurality of grooves.

19. The method of claim 11, further comprising determining whether the adhesive is normally disposed.

20. The method of claim 11, further comprising bending the substrate in the bending area so that the second area of the substrate, the driving circuit chip, and the cover film are disposed under the first area of the substrate.
